(19) United States
(12) Patent Application Publication
(10) Pub. No.: US 2022/0302012 A1
(43) Pub. Date: Sep. 22, 2022

(54) MODULE

(71) Applicant: Murata Manufacturing Co., Ltd., Nagaokakyo-shi (JP)

(72) Inventor: Tetsuya ODA, Nagaokakyo-shi (JP)

(21) Appl. No.: 17/805,883

(22) Filed: Jun. 8, 2022

Related U.S. Application Data
(63) Continuation of application No. PCT/JP2020/045594, filed on Dec. 8, 2020.

(30) Foreign Application Priority Data
Dec. 26, 2019 (JP) 2019-237074

(51) Int. Cl. H01L 23/498; H01L 23/552

(52) U.S. Cl. CPC H01L 23/49838; H01L 23/552; H01L 23/49822

(57) ABSTRACT

A module includes: a substrate having a first surface and a second surface; a sealing resin disposed to cover the first surface and an electronic component; a shield film covering an upper surface and a side surface of the sealing resin and a side surface of the substrate; a lowermost layer ground conductor disposed on the second surface; and an internal ground conductor located within the substrate, separated from the second surface, and disposed to be electrically connected to the shield film at the side surface of the substrate. The lowermost layer ground conductor includes portions different in width from each other as seen in a direction perpendicular to the second surface. With the lowermost layer ground conductor and the internal ground conductor seen in this direction, a region occupied by the internal ground conductor is included in a region occupied by the lowermost layer ground conductor.

### CROSS REFERENCE TO RELATED APPLICATION

This is a continuation of International Application No. PCT/JP2020/045594 filed on Dec. 8, 2020 which claims priority from Japanese Patent Application No. 2019-237074 filed on Dec. 26, 2019. The contents of these applications are incorporated herein by reference in their entireties.

### BACKGROUND OF THE DISCLOSURE

### Field of the Disclosure

The present disclosure relates to a module.

### Description of the Related Art

In recent years, with the increasing number of components in an electronic device such as smart phone as well as the reduction in size and height of the electronic device, there arises a problem of noise interference between electronic components used in the electronic device. To address this problem, it is required to form an electromagnetic shield film on a module product used for communication. Such a shield film can be electrically connected to a conductor exposed on a side surface of a circuit board in the module, to thereby exhibit a shielding effect. Generally, the shield film is electrically connected to a conductor at a ground potential that is exposed on the side surface of the circuit board.

Japanese Patent Laying-Open No. 2018-88460 (PTL 1) discloses an example of the module having a shield film (shield layer) that blocks unnecessary electromagnetic waves to electronic components mounted on a circuit board. In this module, a plurality of electronic components are mounted on one main surface of the circuit board, and a sealing resin layer is applied to seal these electronic components. This module includes a first shield layer covering an upper surface and a side surface of the sealing resin layer as well as a side surface of the circuit board, and a second shield layer covering a partial region of the other main surface of the circuit board and a side surface of the first shield layer.

PTL 1: Japanese Patent Laying-Open No. 2018-88460

### BRIEF SUMMARY OF THE DISCLOSURE

While the configuration disclosed in PTL 1 has two types of shield layers to shield electromagnetic waves, this shielding is not sufficient.

In view of this, an object of the present disclosure is to provide a module that enables sufficient shielding against electromagnetic waves, while ensuring a certain degree of freedom in designing the internal configuration of a substrate.

In order to achieve the above object, a module based on the present disclosure includes: a substrate having a first surface and a second surface; an electronic component mounted on the first surface; a sealing resin disposed to cover the first surface and the electronic component; a shield film covering an upper surface and a side surface of the sealing resin and covering a side surface of the substrate; a lowermost layer ground conductor disposed on the second surface; and an internal ground conductor located within the substrate, separated from the second surface, and disposed to be electrically connected to the shield film at the side surface of the substrate. The lowermost layer ground conductor includes portions different in width from each other as seen in a direction perpendicular to the second surface. With the lowermost layer ground conductor and the internal ground conductor seen in the direction perpendicular to the second surface, a region occupied by the internal ground conductor is included in a region occupied by the lowermost layer ground conductor.

According to the present disclosure, the lowermost layer ground conductor extends, at any position along one side, from the side of the substrate inwardly to a great extent, and therefore, electromagnetic waves can be shielded sufficiently while ensuring a certain degree of freedom in designing the internal configuration of the substrate.

### BRIEF DESCRIPTION OF THE SEVERAL VIEWS OF THE DRAWINGS

FIG. 1 is a perspective view of a module according to Embodiment 1 based on the present disclosure.

FIG. 2 is a plan view of the module according to Embodiment 1 based on the present disclosure.

FIG. 3 is a cross-sectional view along a line III-III in FIG. 2 as seen in the direction of arrows.

FIG. 4 is a partial bottom view of the module according to Embodiment 1 based on the present disclosure.

FIG. 5 is a layout diagram of a conductor pattern of the lowermost layer located in the region shown in FIG. 4.

FIG. 6 is a layout diagram of a resist film located in the region shown in FIG. 4.

FIG. 7 is a cross-sectional view along a line VII-VII in FIG. 4 as seen in the direction of arrows.

FIG. 8 is a cross-sectional view along a line VIII-VIII in FIG. 4 as seen in the direction of arrows.

FIG. 9 illustrates a first example of the shape of an internal ground conductor.

FIG. 10 illustrates a second example of the shape of the internal ground conductor.

FIG. 11 illustrates a third example of the shape of the internal ground conductor.

FIG. 12 illustrates a lowermost layer ground conductor having a recess.

FIG. 13 illustrates an example state where the lowermost layer ground conductor having a recess and an internal ground conductor are laid on each other.

FIG. 14 illustrates another example state where the lowermost layer ground conductor having a recess and an internal ground conductor are laid on each other.

FIG. 15 illustrates a lowermost layer ground conductor having an opening.

FIG. 16 illustrates an example state where the lowermost layer ground conductor having an opening and an internal ground conductor are laid on each other.

FIG. 17 illustrates another example state where the lowermost layer ground conductor having an opening and an internal ground conductor are laid on each other.

FIG. 18 illustrates still another example state where the lowermost layer ground conductor having an opening and an internal ground conductor are laid on each other.

FIG. 19 is a bottom view of a module according to Embodiment 2 based on the present disclosure.

FIG. 20 is a layout diagram of only the conductor pattern of the lowermost layer included in the module according to Embodiment 2 based on the present disclosure.

FIG. 21 is a layout diagram of only conductor patterns disposed in a middle layer included in the module according to Embodiment 2 based on the present disclosure.

### DETAILED DESCRIPTION OF THE DISCLOSURE

Any dimensional ratio shown in the drawings does not necessarily represent the exact actual dimensional ratio, but may be exaggerated for convenience of illustration. In the following description, the concept “top/upper” or “bottom/lower” mentioned herein does not necessarily refer to the exact “top/upper” or “bottom/lower,” but may refer, in a relative sense, to “top/upper” or “bottom/lower” of a posture shown in a drawing(s).

### Embodiment 1

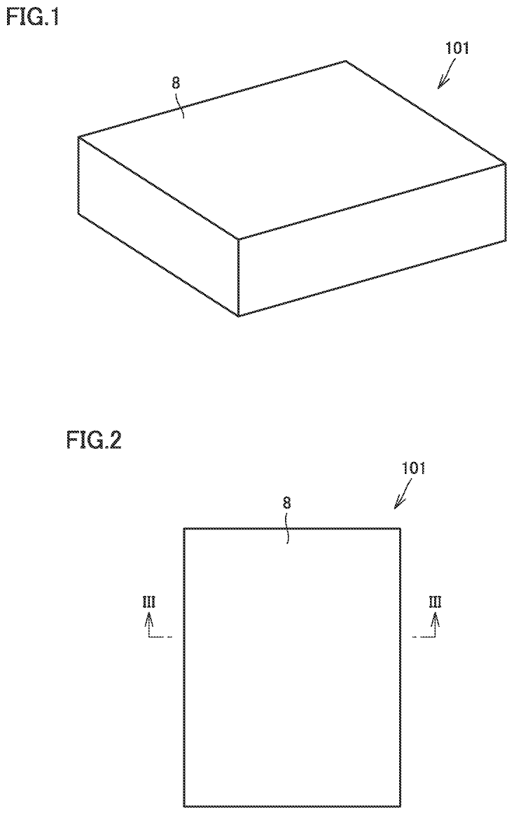

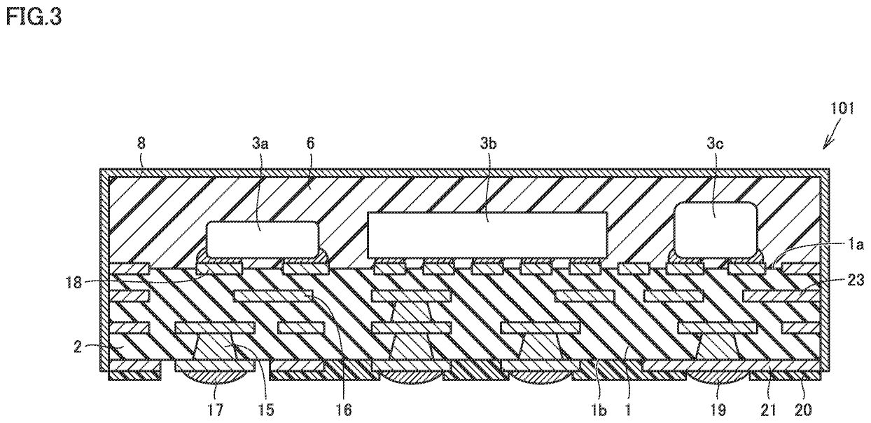

Referring to FIGS. 1 to 11, a module according to Embodiment 1 based on the present disclosure is described. FIG. 1 shows a perspective view of a module 101 according to the present embodiment. FIG. 2 shows a plan view of module 101. FIG. 3 shows a cross-sectional view along a line III-III in FIG. 2 as seen in the direction of arrows.

Module 101 includes: a substrate 1 having a first surface 1a and a second surface 1b; an electronic component 3a mounted on first surface 1a; a sealing resin 6 disposed to cover first surface 1a and electronic component 3a; a shield film 8 covering an upper surface and a side surface of sealing resin 6 and covering a side surface of substrate 1; a lowermost layer ground conductor 21 disposed on second surface 1b; and an internal ground conductor 23 located within substrate 1, separated from second surface 1b, and disposed to be electrically connected to shield film 8 at the side surface of substrate 1. First surface 1a and second surface 1b are respectively a front side and a back side relative to each other. In addition to electronic component 3a, electronic components 3b, 3c are also mounted on first surface 1a. Lowermost layer ground conductor 21 is electrically connected to shield film 8.

Electronic components 3a to 3c are mounted by means of a pad electrode 18 formed on first surface 1a. A conductor pattern 16 is disposed within substrate 1. Conductor pattern 16 forms at least a part of a signal line. Substrate 1 includes an insulating layer 2. Substrate 1 may be a multilayer substrate. The material for insulating layer 2 may be ceramic or resin, for example. Substrate 1 is formed by stacking a plurality of insulating layers into a single substrate. A conductor via 15 is also located within substrate 1. Conductor via 15 is used to electrically connect conductor patterns at different heights to each other. The signal line is formed by appropriately combining conductor via 15 and conductor patterns 16.

An external terminal 17 and a ground terminal 19 are formed on second surface 1b of substrate 1. Second surface 1b is mostly covered with a resist film 20. External terminal 17 includes a pad electrode and a solder disposed on the surface of the pad electrode. By the presence of this solder, external terminal 17 protrudes from the surface of resist film 20. The solder disposed in such a way on the surface of the pad electrode is not a requisite part. No solder may be attached to the surface of the pad electrode.

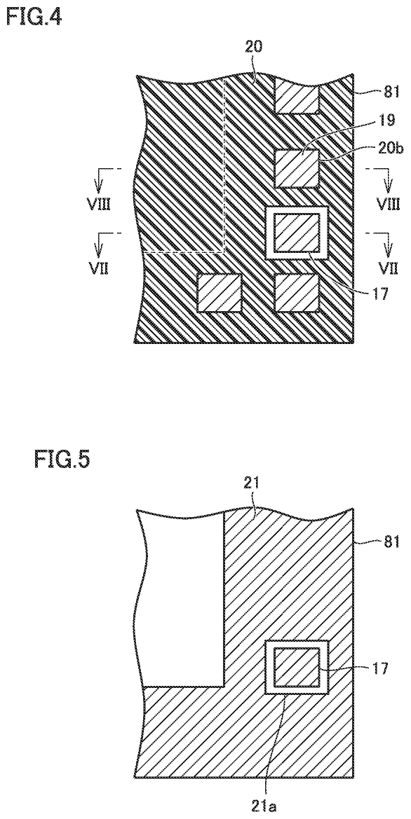

FIG. 4 shows a part of the bottom surface of module 101. The bottom surface of module 101 is mostly covered with resist film 20. On the bottom surface of module 101, external terminal 17 for making an electrical connection as a signal line, and ground terminal 19 at a ground potential are arranged. External terminal 17 and ground terminal 19 are exposed without being covered with resist film 20.

FIG. 5 shows a state corresponding to the state of FIG. 4 from which resist film 20 is removed. A conductor pattern in the lowermost layer of substrate 1 is shown here. The conductor pattern shown in FIG. 5 includes lowermost layer ground conductor 21 and external terminal 17 of the signal line. External terminal 17 is located inside an opening 21a formed in lowermost layer ground conductor 21. External terminal 17 is separated from lowermost layer ground conductor 21.

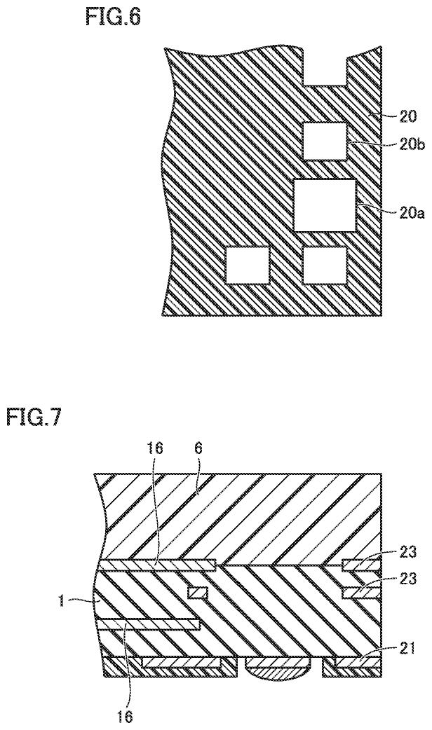

FIG. 6 shows resist film 20 of the region shown in FIG. 4. FIG. 4 corresponds to a combination of FIG. 5 and resist film 20 shown in FIG. 6 covering the portion shown in FIG. 5. Resist film 20 has an opening 20a and an opening 20b. Opening 20a corresponds to opening 21a in lowermost layer ground conductor 21 and is substantially identical in size to opening 21a. Opening 20b exposes a part of lowermost layer ground conductor 21 to serve as ground terminal 19.

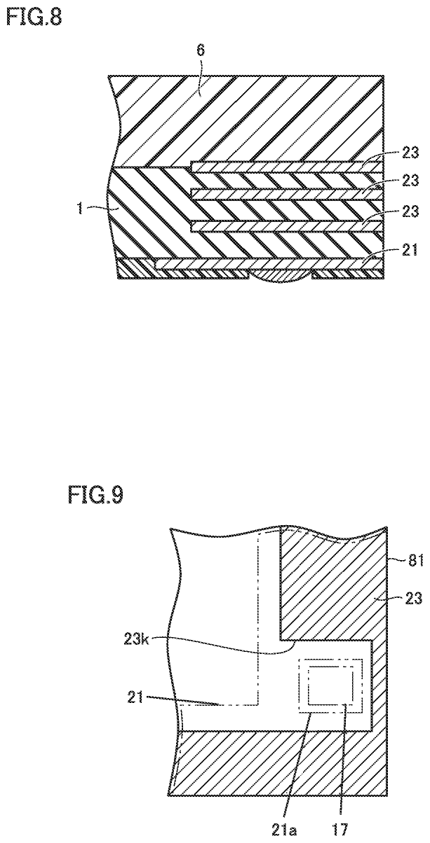

FIG. 7 shows a cross-sectional view along a line VII-VII in FIG. 4 as seen in the direction of arrows. FIG. 8 shows a cross-sectional view along a line VIII-VIII in FIG. 4 as seen in the direction of arrows.

The right side as seen in FIG. 5 is referred to as a first side 81, to further proceed with the description. For module 101 according to the present embodiment, with lowermost layer ground conductor 21 seen in the direction perpendicular to second surface 1b, a first point and a second point can be selected in the following manner along first side 81, which is one of the geometric line segments of substrate 1, i.e., the first and second points can be selected such that the length of lowermost layer ground conductor 21 extending perpendicularly to first side 81, from the first point toward the inside of substrate 1, to a point of the first discontinuation of lowermost layer ground conductor 21, differs from the length of lowermost layer ground conductor 21 extending perpendicularly to first side 81, from the second point toward the inside of substrate 1, to a point of the first discontinuation of lowermost layer ground conductor 21. In other words, lowermost layer ground conductor 21 is not constant in width, but includes portions different in width from each other.

FIG. 9 shows a first example of the shape of internal ground conductor 23, with internal ground conductor 23 seen in the direction perpendicular to second surface 1b. In FIG. 9, the outline of lowermost layer ground conductor 21 and the outline of external terminal 17 are indicated by a dashed-and-double-dotted line. In this example, a recess 23k is formed in internal ground conductor 23. Opening 21a of lowermost layer ground conductor 21 is located within recess 23k.

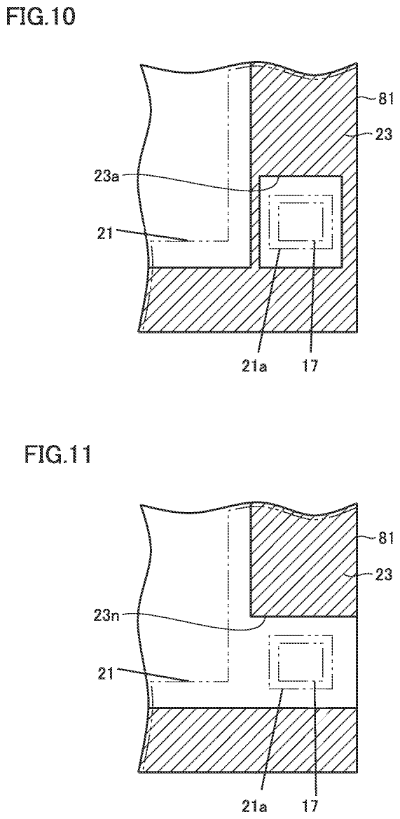

FIG. 10 shows a second example of the shape of internal ground conductor 23. In FIG. 10, an opening 23a is formed in internal ground conductor 23. Opening 21a of lowermost layer ground conductor 21 is located within opening 23a.

FIG. 11 shows a third example of the shape of internal ground conductor 23. In FIG. 11, a discontinued portion 23n is formed in internal ground conductor 23. Opening 21a of lowermost layer ground conductor 21 is located within discontinued portion 23n.

In any of the first to third examples of the shape of internal ground conductor 23 shown herein, at any position along first side 81, with lowermost layer ground conductor 21 and internal ground conductor 23 seen in the direction perpendicular to second surface 1b, the region occupied by internal ground conductor 23 is included in the region occupied by lowermost layer ground conductor 21. In other words, when any point is selected on internal ground conductor 23, lowermost layer ground conductor 21 is always present at the position onto which the selected point is projected perpendicularly. As seen in the direction perpendicular to second surface 1b, internal ground conductor 23 never extends beyond lowermost layer ground conductor 21. The fact that Region A is “included” in Region B also refers to the fact that Region A is identical to Region B. A simplified model is described later herein.

According to the present embodiment in which the module is configured to have lowermost layer ground conductor 21 that is not constant in width, lowermost layer ground conductor 21 extends, at any position along first side 81, from the side of substrate 1 inwardly to a great extent, and therefore, electromagnetic waves can be shielded sufficiently while ensuring a certain degree of freedom in designing the internal configuration of substrate 1. Internal ground conductor 23 extends to a smaller extent than lowermost layer ground conductor 21, and therefore, a greater space can be ensured for arranging interconnections for example in substrate 1, which ensures the degree of freedom of design.

As illustrated in connection with the present embodiment, preferably lowermost layer ground conductor 21 has opening 21a or a recess 21k in which a signal line is to be disposed, and lowermost layer ground conductor 21 is separated from the signal line. At the height of lowermost layer ground conductor 21, the signal line is formed as external terminal 17, and therefore, lowermost layer ground conductor 21 is separated from external terminal 17.

As illustrated in connection with the present embodiment, preferably resist film 20 partially covers lowermost layer ground conductor 21, and resist film 20 has opening 20b for exposing a part of lowermost layer ground conductor 21. This configuration can be employed to clearly separate terminals from each other by resist film 20, when the module is mounted on a mother board or the like by a solder, and thereby prevent the solder from flowing to another terminal and thereby causing short circuit.

The presence of resist film 20 is not a requisite condition. The module may have a configuration with no resist film 20 covering the surface of lowermost layer ground conductor 21 for example.

Description with Simplified Model

For the sake of facilitating understanding, the following description is given with reference to a further simplified model.

### Example 1: Lowermost Layer Ground Conductor Having Recess

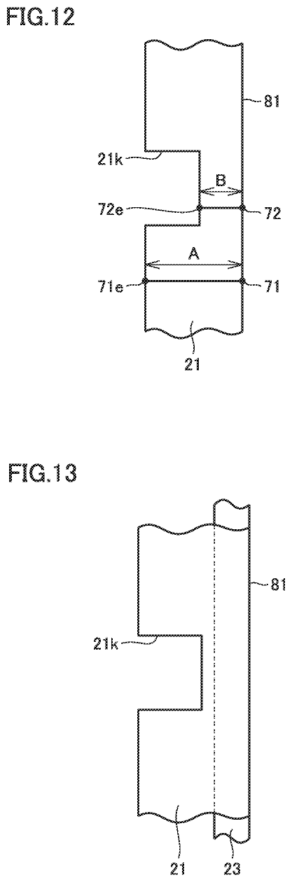

First, a lowermost layer ground conductor having a recess is described. FIG. 12 shows a part of lowermost layer ground conductor 21. In this example, the right side is first side 81 which is one of the geometric line segments of substrate 1. Specifically, the leftward direction as seen in this drawing corresponds to the direction toward the inside of substrate 1. Lowermost layer ground conductor 21 has recess 21k. See a first point 71 and a second point 72 selected along first side 81. Since recess 21k is present, Length A of lowermost layer ground conductor 21 extending perpendicularly to first side 81, from first point 71 toward the inside of substrate 1, to a point of first discontinuation 71e of lowermost layer ground conductor 21, differs from Length B of lowermost layer ground conductor 21 extending perpendicularly to first side 81, from second point 72 toward the inside of substrate 1, to a point of first discontinuation 72e of lowermost layer ground conductor 21. In the example shown in FIG. 12, such first point 71 and second point 72 can be selected on first side 81. In other words, lowermost layer ground conductor 21 is not constant in width but includes portions different in width from each other.

FIG. 13 shows lowermost layer ground conductor 21 and internal ground conductor 23 that are laid on each other. In the example shown in FIG. 13, lowermost layer ground conductor 21 has recess 21k, while internal ground conductor 23 has no recess and extends with a constant width. With lowermost layer ground conductor 21 and internal ground conductor 23 seen in the direction perpendicular to second surface 1b, the region occupied by internal ground conductor 23 is included in the region occupied by lowermost layer ground conductor 21, at any position along first side 81. Specifically, at any position along first side 81, internal ground conductor 23 never extends beyond lowermost layer ground conductor 21. At any position along first side 81, internal ground conductor 23 hides behind lowermost layer ground conductor 21.

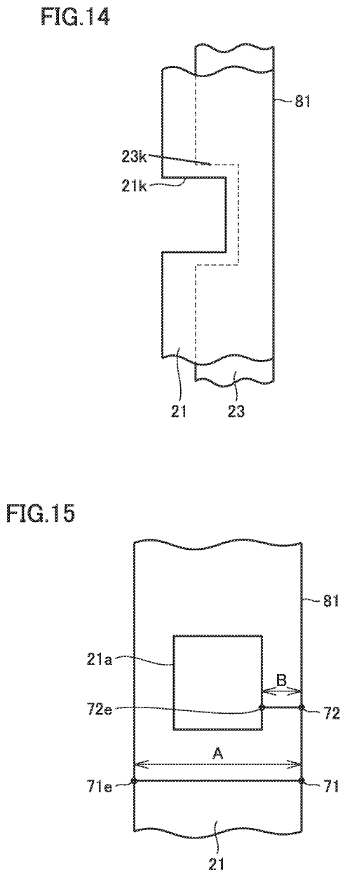

Another example may be the one as shown in FIG. 14. In this example, lowermost layer ground conductor 21 has recess 21k while internal ground conductor 23 has a recess 23k. Recess 23k extends further behind recess 21k, and therefore, internal ground conductor 23 never extends beyond lowermost layer ground conductor 21 even in recess 21k.

### Example 2: Lowermost Layer Ground Conductor Having Opening

Next, a lowermost layer ground conductor having an opening is described. FIG. 15 shows a part of lowermost layer ground conductor 21. In this example, the right side is first side 81. Lowermost layer ground conductor 21 has an opening 21a. See a first point 71 and a second point 72 selected along first side 81. Since opening 21a is present, Length A of lowermost layer ground conductor 21 extending perpendicularly to first side 81, from first point 71 toward the inside of substrate 1, to a point of first discontinuation 71e of lowermost layer ground conductor 21, differs from Length B of lowermost layer ground conductor 21 extending perpendicularly to first side 81, from second point 72 toward the inside of substrate 1, to a point of first discontinuation 72e of lowermost layer ground conductor 21. In the example shown in FIG. 15, such first point 71 and second point 72 can be selected on first side 81. In this example, lowermost layer ground conductor 21 is also regarded as being not constant in width but including portions different in width from each other.

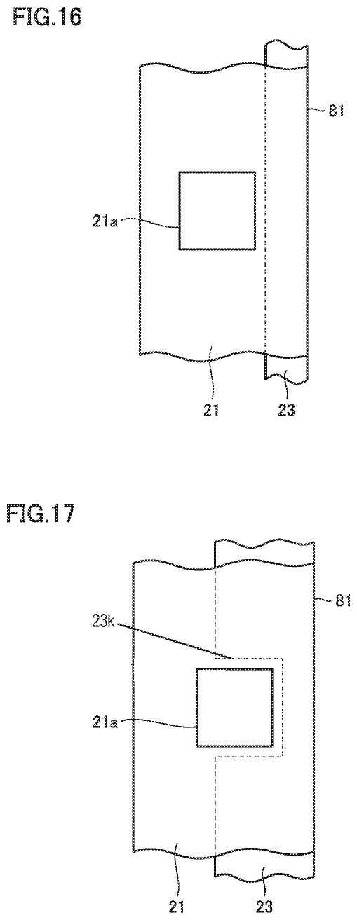

FIG. 16 shows lowermost layer ground conductor 21 and internal ground conductor 23 that are laid on each other. In the example shown in FIG. 16, lowermost layer ground conductor 21 has opening 21a, while internal ground conductor 23 has no opening and extends with a constant width. With lowermost layer ground conductor 21 and internal ground conductor 23 seen in the direction perpendicular to second surface 1b, the region occupied by internal ground conductor 23 is included in the region occupied by lowermost layer ground conductor 21, at any position along first side 81. Specifically, at any position along first side 81, internal ground conductor 23 never extends beyond lowermost layer ground conductor 21. At any position along first side 81, internal ground conductor 23 hides behind lowermost layer ground conductor 21.

A still another example may be the one as shown in FIG. 17. In this example, lowermost layer ground conductor 21 has opening 21a, while internal ground conductor 23 does not have an opening but has recess 23k. Recess 23k extends further behind opening 21a, and therefore, internal ground conductor 23 never extends beyond lowermost layer ground conductor 21 even in opening 21a.

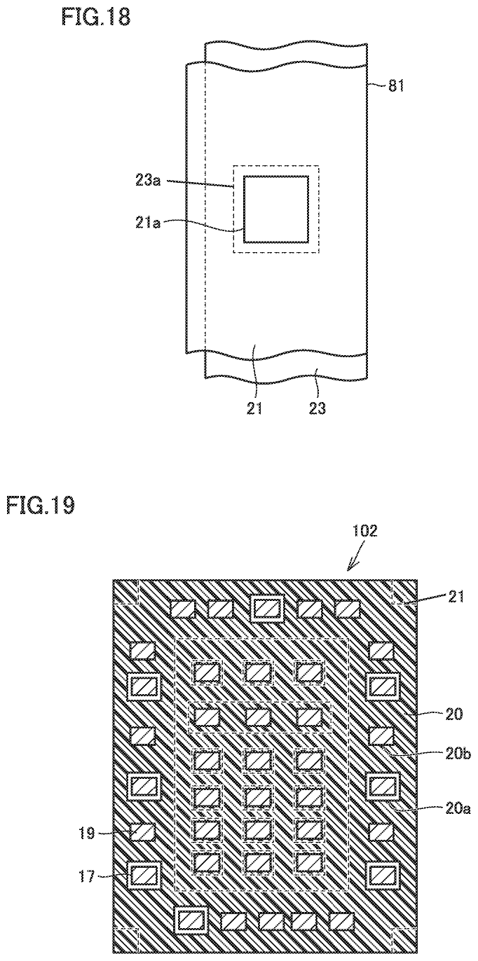

A further example may be the one as shown in FIG. 18. In this example, lowermost layer ground conductor 21 has opening 21a, while internal ground conductor 23 has opening 23a. Opening 23a is larger than opening 21a.

Thus, lowermost layer ground conductor 21 is configured to be inconstant in width and include portions different in width from each other. In this way, improvement in the degree of freedom in arranging terminals on the bottom surface which is a surface of the module to be mounted, and/or increase in the number of terminals for signal lines, for example, can be achieved.

To fabricate the module according to the present embodiment, firstly a mass substrate of a large size including a plurality of modules is prepared, electronic components are mounted as required on the surface of the mass substrate, and thereafter a resin is molded to seal these electronic components. Resin molding may be done by any method such as transfer molding, compression molding, or dipping of liquid resin, for example. After molding the resin, the mass substrate is separated into pieces by any means such as dicer, laser, or scribing, for example. In this way, individual substrate 1 having its surface on which an electronic component(s) is mounted and covered with sealing resin 6 is obtained.

In order to expose lowermost layer ground conductor 21 and internal ground conductor 23 from the side surface of substrate 1, a conductor pattern having a shape corresponding to the shape of these conductors may be disposed in advance on the surface of or inside the mass substrate, such that a cross section of the conductor pattern is exposed from a side surface generated newly as a result of separation of the mass substrate into pieces of the size of individual modules.

In order to electrically connect, at the side surface of substrate 1, shield film 8 to lowermost layer ground conductor 21 and internal ground conductor 23, the mass substrate may be separated into pieces of the size of individual modules, and thereafter spattering may be performed with the side surface of substrate 1 exposed, to thereby form shield film 8.

### Embodiment 2

Referring to FIGS. 19 to 21, a module according to Embodiment 2 based on the present disclosure is described. FIG. 19 shows a bottom view of a module 102 according to the present embodiment. The bottom surface is mostly covered with resist film 20. In FIG. 19, a conductor pattern of the lowermost layer hiding behind resist film 20 is indicated by a broken line. Only the conductor pattern of the lowermost layer included in the module 102 is shown in FIG. 20. The conductor pattern of the lowermost layer includes a lowermost layer ground conductor 21 and external terminal 17 of a signal line. Lowermost layer ground conductor 21 is disposed along the outer periphery of the bottom surface. The conductor pattern of the lowermost layer may include, in addition to lowermost layer ground conductor 21, another ground terminal that does not connect to lowermost layer ground conductor 21. External terminal 17 is disposed in each opening 21a formed in lowermost layer ground conductor 21.

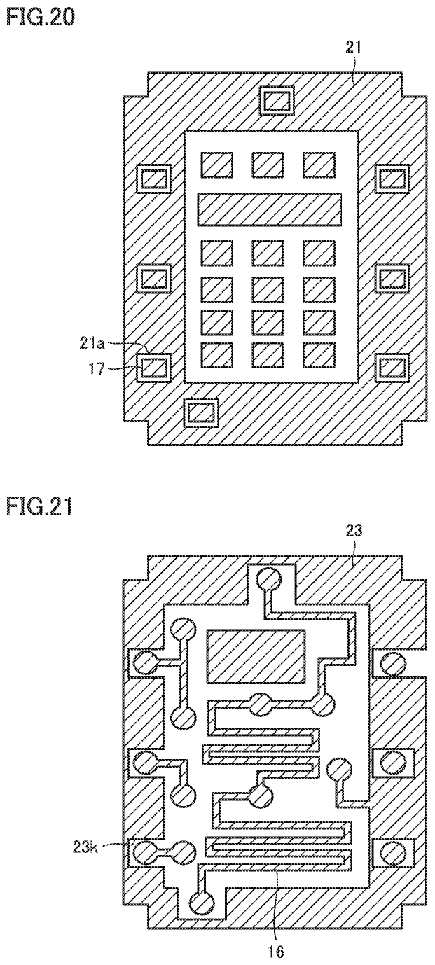

Only conductor patterns disposed in a middle layer, not the lowermost layer, of substrate 1 are shown in FIG. 21. A group of the conductor patterns located at this height includes internal ground conductor 23 and conductor pattern 16. Internal ground conductor 23 is disposed along the outer periphery. Internal ground conductor 23 has recess 23k. A conductor pattern forming a part of a signal line is disposed within recess 23k.

As illustrated in connection with the present embodiment, preferably lowermost layer ground conductor 21 is disposed along the entire periphery of substrate 1.

As illustrated in connection with the present embodiment, the presence of lowermost layer ground conductor 21 disposed along the entire periphery of substrate 1 enables sufficient shielding of electromagnetic waves.

More than one of the above-described embodiments may be employed in an appropriate combination.

The above embodiments disclosed herein are given by way of illustration in all respects, not by way of limitation. The scope of the present disclosure is defined by claims, and encompasses all modifications and variations equivalent in meaning and scope to the claims.

1 substrate; 1a first surface; 1b second surface; 2 insulating layer; 3a, 3b, 3c electronic component; 6 sealing resin; 8 shield film; 15 conductor via; 16 conductor pattern; 17 external terminal; 18 pad electrode; 19 ground terminal; 20 resist film; 20a, 20b opening (of the resist film); 21 lowermost layer ground conductor; 21a opening (of the lowermost layer ground conductor); 21k recess (of the lowermost layer ground conductor); 23 internal ground conductor; 23a opening (of the internal ground conductor); 23k recess (of the internal ground conductor); 23n discontinued portion (of the internal ground conductor); 71 first point; 71e, 72e point; 72 second point; 81 first side; 101, 102 module

1. A module comprising:
a substrate having a first surface and a second surface;
an electronic component mounted on the first surface;
a sealing resin disposed to cover the first surface and the electronic component;
a shield film covering an upper surface and a side surface of the sealing resin and covering a side surface of the substrate;
a lowermost layer ground conductor disposed on the second surface; and
an internal ground conductor located within the substrate, separated from the second surface, and disposed to be electrically connected to the shield film at the side surface of the substrate, wherein
the lowermost layer ground conductor includes portions different in width from each other as seen in a direction perpendicular to the second surface, and
with the lowermost layer ground conductor and the internal ground conductor seen in the direction perpendicular to the second surface, a region occupied by the internal ground conductor is included in a region occupied by the lowermost layer ground conductor.

2. The module according to claim 1, wherein the lowermost layer ground conductor has an opening or a recess for disposing a signal line, and the lowermost layer ground conductor is separated from the signal line.

3. The module according to claim 2, wherein the lowermost layer ground conductor is disposed along an entire periphery of the substrate.

4. The module according to claim 1, further comprising a resist film partially covering the lowermost layer ground conductor, wherein the resist film has an opening for exposing a part of the lowermost layer ground conductor.

5. The module according to claim 1, wherein the region occupied by the internal ground conductor is different from the region occupied by the lowermost layer ground conductor.

6. The module according to claim 2, further comprising a resist film partially covering the lowermost layer ground conductor, wherein the resist film has an opening for exposing a part of the lowermost layer ground conductor.

7. The module according to claim 3, further comprising a resist film partially covering the lowermost layer ground conductor, wherein the resist film has an opening for exposing a part of the lowermost layer ground conductor.

8. The module according to claim 2, wherein the region occupied by the internal ground conductor is different from the region occupied by the lowermost layer ground conductor.
